(19) United States
(12) Patent Application Publication
(10) Pub. No.: US 2021/0202298 A1
(43) Pub. Date: Jul. 1, 2021

(54) SEMICONDUCTOR DEVICE MANUFACTURING METHOD AND SEMICONDUCTOR DEVICE MANUFACTURING SYSTEM

(71) Applicant: Tokyo Electron Limited, Tokyo (JP)

(72) Inventors: Tatsuya YAMAGUCHI, Nirasaki City (JP); Syuji NOZAWA, Nirasaki City (JP)

(21) Appl. No.: 17/128,917

(22) Filed: Dec. 21, 2020

(30) Foreign Application Priority Data
Dec. 27, 2019 (JP) 2019-239758

(51) Int. Cl. H01L 21/764; H01L 21/3105; H01L 21/02

(52) U.S. Cl. CPC H01L 21/764; C23C 16/345; H01L 21/0217; H01L 21/31058

(57) ABSTRACT

A semiconductor device manufacturing method includes laminating a thermally-decomposable organic material on a substrate having a recess formed therein, laminating a silicon nitride film on the organic material, and heating the substrate to a predetermined temperature so as to thermally decompose the organic material, and to desorb the organic material under the silicon nitride film through the silicon nitride film so as to form an air gap between the silicon nitride film and the recess. In laminating the silicon nitride film, the silicon nitride film is laminated on the organic material with microwave plasma in a state in which a temperature of the substrate is maintained at 200 degrees C. or lower.

### CROSS-REFERENCE TO RELATED APPLICATION

This application is based upon and claims the benefit of priority from Japanese Patent Application No. 2019-239758, filed on Dec. 27, 2019, the entire contents of which are incorporated herein by reference.

### TECHNICAL FIELD

Various aspects and embodiments of the disclosure relate to a semiconductor device manufacturing method and a semiconductor device manufacturing system.

### BACKGROUND

For example, Patent Document 1 below discloses a technique for reducing the relative dielectric constant of an interlayer insulating film by forming an air gap in the interlayer insulating film in a semiconductor device having a multilayer structure. In this technique, when the interlayer insulating film is buried in a recess in a substrate, a space (void) that causes a defective embedding is formed in the recess, and the formed void is used as the air gap.

### PRIOR ART DOCUMENT

### Patent Document

Patent Document 1: Japanese Laid-Open Patent Publication No. 2012-054307

### SUMMARY

According to one embodiment of the present disclosure, a semiconductor device manufacturing method includes: laminating a thermally-decomposable organic material on a substrate having a recess formed therein; laminating a silicon nitride film on the organic material; and heating the substrate to a predetermined temperature so as to thermally decompose the organic material, and to desorb the organic material under the silicon nitride film through the silicon nitride film so as to form an air gap between the silicon nitride film and the recess. In laminating the silicon nitride film, the silicon nitride film is laminated on the organic material with microwave plasma in a state in which a temperature of the substrate is maintained at 200 degrees C. or lower.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a system configuration view illustrating an example of a manufacturing system according to an embodiment of the present disclosure.

FIG. 2 is a schematic cross-sectional view illustrating an example of a laminating apparatus according to an embodiment of the present disclosure.

FIG. 3 is a schematic cross-sectional view illustrating an example of a plasma processing apparatus according to an embodiment of the present disclosure.

FIG. 4 is a schematic cross-sectional view illustrating an example of an annealing apparatus according to an embodiment of the present disclosure.

FIG. 5 is a flowchart illustrating an example of a semiconductor device manufacturing method.

FIG. 6 is a view illustrating an example of a process of manufacturing the semiconductor device.

FIG. 7 is a view illustrating an example of a process of manufacturing the semiconductor device.

FIG. 8 is a view illustrating an example of a process of manufacturing the semiconductor device.

FIG. 9 is a view illustrating an example of a process of manufacturing the semiconductor device.

FIG. 10 is a view showing an example of test results.

FIG. 11 is a diagram illustrating an example of a relationship between a density and a thickness of a sealing film.

### DETAILED DESCRIPTION

Hereinafter, embodiments of a semiconductor device manufacturing method and a semiconductor device manufacturing system disclosed herein will be described in detail with reference to the drawings. The following embodiments do not limit the semiconductor device manufacturing method and the semiconductor device manufacturing system disclosed herein. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

The shape and size of a void formed as a defective embedding depend on the width or depth of a recess or the like. For example, when the width of the recess is narrow, a large void is formed in the lower portion of the recess, but when the width of the recess is wide, almost no void may be formed in the lower portion of the recess. In addition, the shape and size of the void formed in a recess may vary depending on the position of the recess on the substrate and the position of the recess in a semiconductor manufacturing apparatus. Therefore, it is difficult to form a void having a desired shape and size in a recess having an arbitrary shape.

Therefore, a thermally-decomposable organic material is laminated in a recess of a substrate, a sealing film is laminated on the organic material, and then the substrate is heated. As a result, the thermally-decomposed organic material may be separated from the recess through the sealing film. Thus, it is possible to form an air gap having a shape corresponding to the shape of the organic material between the recess and the sealing film.

However, when a film density of the sealing film is too high, the thermally-decomposed organic material cannot pass through the sealing film and remains as a residue inside the recess. Thus, it becomes difficult to form an air gap having a desired shape between the recess and the sealing film.

On the other hand, when the film density of the sealing film is too low, the thermally-decomposed organic material is desorbed via the sealing film. However, when another film is laminated on the sealing film in a subsequent step, the film may be laminated in the recess through the sealing film. Therefore, it becomes difficult to form an air gap having a desired shape between the recess and the sealing film.

Therefore, the present disclosure provides a technique for forming an air gap having a desired shape.

### [Configuration of Manufacturing System 10]

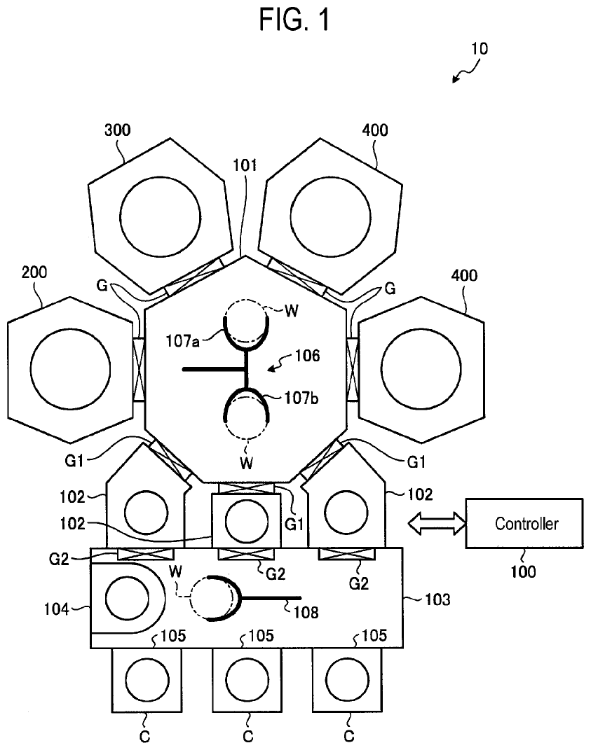

FIG. 1 is a system configuration view illustrating an example of a manufacturing system 10 according to an embodiment of the present disclosure. The manufacturing system 10 includes a laminating apparatus 200, a plasma processing apparatus 300, and a plurality of annealing apparatuses 400. The manufacturing system 10 is a multi-chamber-type vacuum-processing system. The manufacturing system 10 uses the laminating apparatus 200, the plasma processing apparatus 300, and the annealing apparatuses 400 to form an air gap in a substrate W used for a semiconductor device.

The laminating apparatus 200 laminates a film of a thermally-decomposable organic material on the surface of the substrate W in which a recess is formed. In the present embodiment, the thermally-decomposable organic material is a polymer having a urea bond generated by the polymerization of multiple types of monomers. The plasma processing apparatus 300 uses microwave plasma to laminate a sealing film on the organic material laminated in the recess of the substrate W. The annealing apparatus 400 heats the substrate W on which the sealing film is laminated so as to thermally decompose the organic material under the sealing film and to desorb the organic material through the sealing film. As a result, an air gap is formed between the recess of the substrate W and the sealing film.

The laminating apparatus 200, the plasma processing apparatus 300, and the plurality of annealing apparatuses 400 are connected to four sidewalls of a vacuum transfer chamber 101 having a heptagonal planar shape via gate valves G, respectively. The inside of the vacuum transfer chamber 101 is exhausted by a vacuum pump, and is maintained at a predetermined degree of vacuum. A transfer mechanism 106, such as a robot arm, is provided inside the vacuum transfer chamber 101. The transfer mechanism 106 transfers the substrate W between the laminating apparatus 200, the plasma processing apparatus 300, each annealing apparatus 400, and each load-lock chamber 102. The transfer mechanism 106 has two arms 107a and 107b, which are independently movable.

Three load-lock chambers 102 are connected to the other three sidewalls of the vacuum transfer chamber 101 via gate valves G1, respectively. Each of the three load-lock chambers 102 is connected to an atmospheric transfer chamber 103 via a gate valve G2.

A side surface of the atmospheric transfer chamber 103 is provided with a plurality of ports 105, each of which is configured to mount thereon a carrier (e.g., front-opening unified pod (FOUP)) C for accommodating the substrate W. In addition, an alignment chamber 104 is provided on a sidewall of the atmospheric transfer chamber 103 to align the substrate W. A down-flow of clean air is formed inside the atmospheric transfer chamber 103.

A transfer mechanism 108, such as a robot arm, is provided inside the atmospheric transfer chamber 103. The transfer mechanism 108 transfers the substrate W between each carrier C, each load-lock chamber 102, and the alignment chamber 104.

A controller 100 has a memory, a processor, and an input/output interface. The memory stores a program executed by the processor and a recipe including conditions for each process, and the like. The processor executes the program read from the memory and controls each part of the manufacturing system 10 via the input/output interface based on the recipe stored in the memory.

### [Laminating Apparatus 200]

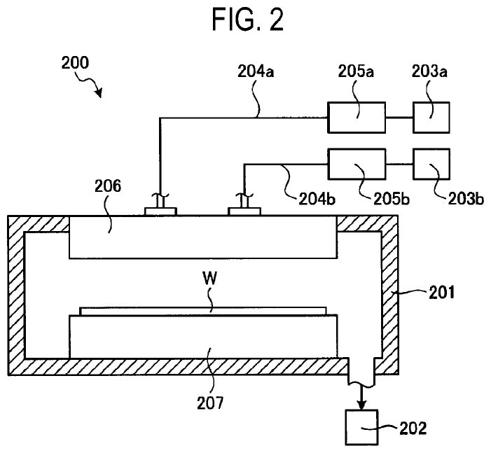

FIG. 2 is a schematic cross-sectional view illustrating an example of the laminating apparatus 200 according to an embodiment of the present disclosure. In the present embodiment, the laminating apparatus 200 is, for example, a chemical vapor deposition (CVD) apparatus.

The laminating apparatus 200 has a container 201 and an exhaust device 202. The exhaust device 202 exhausts an inner gas of the container 201. The inside of the container 201 is controlled by the exhaust device 202 to a predetermined vacuum atmosphere.

Multiple types of raw material monomers are supplied to the container 201. The multiple types of raw material monomers are, for example, isocyanate and amine A raw material source 203a configured to accommodate isocyanate as a liquid is connected to the container 201 via a supply pipe 204a. In addition, a raw material source 203b configured to accommodate amine as a liquid is connected to the container 201 via a supply pipe 204b.

The isocyanate liquid supplied from the raw material source 203a is vaporized by a vaporizer 205a provided in the supply pipe 204a. Then, isocyanate vapor is introduced into a shower head 206, which is a gas ejection part, through the supply pipe 204a. In addition, the amine liquid supplied from the raw material source 203b is vaporized by a vaporizer 205b provided in the supply pipe 204b. Then, amine vapor is introduced into the shower head 206.

The shower head 206 is provided on, for example, the upper portion of the container 201, and has a large number of ejection holes formed in the bottom surface thereof. The shower head 206 ejects the isocyanate vapor and the amine vapor introduced through the supply pipe 204a and the supply pipe 204b into the container 201 from the respective ejection holes in the form of a shower.

A stage 207 having a temperature control mechanism (not illustrated) is provided inside the container 201. The substrate W is placed on the stage 207. The stage 207 controls a temperature of the substrate W using the temperature control mechanism so that the wafer W has a temperature suitable for vapor deposition polymerization of the raw material monomers, which are supplied from the raw material source 203a and the raw material source 203b, respectively. The temperature suitable for the vapor deposition polymerization may be determined according to the types of raw material monomers, and may be, for example, 40 degrees C. to 150 degrees C.

By causing vapor deposition polymerization reaction of two types of raw material monomers on the surface of the substrate W using the laminating apparatus 200, an organic material is laminated on the surface of the substrate W in which the recess is formed. When the two types of raw material monomers are isocyanate and amine, a polymer film of polyurea is laminated on the surface of the substrate W.

### [Plasma Processing Apparatus 300]

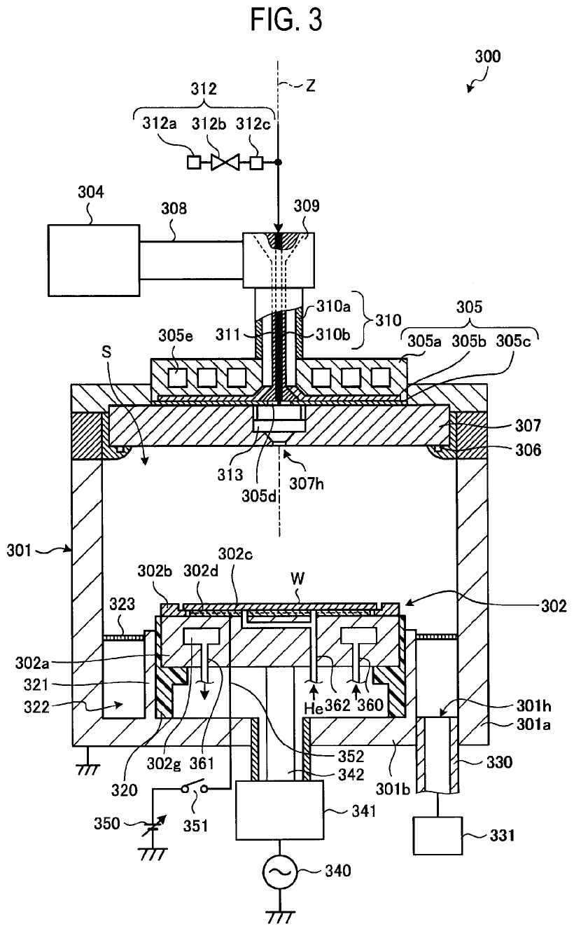

FIG. 3 is a schematic cross-sectional view illustrating an example of the plasma processing apparatus 300 according to an embodiment of the present disclosure. The plasma processing apparatus 300 includes a processing container 301 and a microwave output device 304.

The processing container 301 is made of, for example, aluminum having an anodized surface, and is formed in a substantially cylindrical shape. The processing container 301 provides a substantially cylindrical processing space S defined therein. The processing container 301 is securely grounded. The processing container 301 has a sidewall 301a and a bottom portion 301b. The central axis line of the sidewall 301a is defined as an axis line Z. The bottom portion 301b is provided on the lower end side of the sidewall 301a. The bottom portion 301b is provided with an exhaust port 301h for gas exhaust. The upper end portion of the sidewall 301a is open.

A dielectric window 307 is provided at the upper end portion of the sidewall 301a. The opening at the upper end portion of the sidewall 301a is closed from above by the dielectric window 307. The bottom surface of the dielectric window 307 faces the processing space S. An O-ring 306 is disposed between the dielectric window 307 and the upper end portion of the sidewall 301a.

A stage 302 is provided inside the processing container 301. The stage 302 is provided so as to face the dielectric window 307 in the direction of the axis line Z. A space between the stage 302 and the dielectric window 307 corresponds to the processing space S. The substrate W is placed on the stage 302.

The stage 302 has a base 302a and an electrostatic chuck 302c. The base 302a is made of a conductive material, such as aluminum, and is formed in an approximate disk shape. The base 302a is disposed inside the processing container 301 such that the central axis line of the base 302a substantially coincides with the axis line Z.

The base 302a is formed of an insulating material, and is supported by a tubular support part 320 extending in a direction along the axis line Z. A conductive tubular support part 321 is provided on the outer circumference of the tubular support part 320. The tubular support part 321 extends from the bottom portion 301b of the processing container 301 towards the dielectric window 307 along the outer circumference of the tubular support part 320. An annular exhaust path 322 is formed between the tubular support part 321 and the sidewall 301a.

An annular baffle plate 323, in which a plurality of through-holes is formed in the thickness direction thereof, is provided in the upper portion of the exhaust path 322. The exhaust port 301h described above is provided below the baffle plate 323. An exhaust device 331 including a vacuum pump, such as a turbo molecular pump, and an automatic pressure control valve, and the like, is connected to the exhaust port 301h through an exhaust pipe 330. The exhaust device 331 is capable of reducing the pressure of the processing space S to a predetermined degree of vacuum.

The base 302a also functions as a high-frequency electrode. An RF power supply 340 configured to output an RF signal for RF bias is electrically connected to the base 302a via a power feeding rod 342 and a matching unit 341. The RF power supply 340 supplies, to the base 302a, bias power having a predetermined frequency (e.g., 13.56 MHz) suitable for controlling the energy of ions drawn into the substrate W via the matching unit 341 and the power feeding rod 342.

The matching unit 341 accommodates a matcher for matching an impedance on the side of the RF power supply 340 with an impedance on the side of load, mainly such as an electrode, plasma, and the processing container 301. A blocking capacitor for self-bias generation is included in the matcher.

The electrostatic chuck 302c is provided on the top surface of the base 302a. The electrostatic chuck 302c holds the substrate W by suction due to an electrostatic force. The electrostatic chuck 302c has an appropriate disk shape, and has a heater 302d buried therein. A heater power supply 350 is electrically connected to the heater 302d via a wire 352 and a switch 351. The heater 302d heats the substrate W placed on the electrostatic chuck 302c by the electric power supplied from the heater power supply 350. An edge ring 302b is provided on the base 302a. The edge ring 302b is disposed so as to surround the substrate W and the electrostatic chuck 302c. The stage 302 is sometimes called a focus ring.

A flow path 302g is provided inside the base 302a. Coolant is supplied into the flow path 302g from a chiller unit (not illustrate) through a pipe 360. The coolant supplied into the flow path 302g is returned to the chiller unit through a pipe 361. The temperature of the base 302a is controlled by circulating the coolant, the temperature of which is controlled by the chiller unit, in the flow path 302g of the base 302a. The temperature of the substrate W on the electrostatic chuck 302c is controlled by the coolant flowing in the base 302a and the heater 302d inside the electrostatic chuck 302c. In the present embodiment, the temperature of the substrate W is controlled to 200 degrees C. or lower (e.g., 150 degrees C.). The heater 302d inside the electrostatic chuck 302c is an example of a temperature controller.

In addition, the stage 302 is provided with a pipe 362 for supplying a heat transfer gas, such as a He gas, between the electrostatic chuck 302c and the substrate W.

The microwave output device 304 outputs microwaves for exciting the processing gas supplied into the processing container 301. The microwave output device 304 generates microwaves having a frequency of, for example, 2.4 GHz. The microwave output device 304 is an example of a plasma processing part.

An output part of the microwave output device 304 is connected to one end of a waveguide 308. The other end of the waveguide 308 is connected to a mode converter 309. The mode converter 309 converts a mode of the microwaves output from the waveguide 308, and supplies the microwaves after the mode conversion to an antenna 305 through a coaxial waveguide 310.

The coaxial waveguide 310 includes an outer conductor 310a and an inner conductor 310b. The outer conductor 310a and the inner conductor 310b have a substantially cylindrical shape, and are disposed above the antenna 305 such that central axes of the outer conductor 310a and the inner conductor 310b substantially coincide with the axis line Z.

The antenna 305 includes a cooling jacket 305a, a dielectric plate 305b, and a slot plate 305c. The slot plate 305c is formed of a conductive material in an appropriate disk shape. The slot plate 305c is provided on the top surface of the dielectric window 307 such that the central axis line of the slot plate 305c coincides with the axis line Z. A plurality of slot holes are formed in the slot plate 305c. The plurality of slot holes, two of which are paired, are arranged around the central axis line of the slot plate 305c.

The dielectric plate 305b is formed of a dielectric material, such as quartz, in an appropriate disk shape. The dielectric plate 305b is disposed on the slot plate 305c such that the central axis line of the dielectric plate 305b substantially coincides with the axis line Z. The cooling jacket 305a is provided on the dielectric plate 305b.

The cooling jacket 305a is formed of a material having a conductive surface, and has a flow path 305e formed therein. Coolant is supplied into the flow path 305e from a chiller unit (not illustrated). A lower end of the outer conductor 310a is electrically connected to an upper surface of the cooling jacket 305a. In addition, a lower end of the inner conductor 310b is electrically connected to the slot plate 305c through an opening formed in the central portion of the cooling jacket 305a and the dielectric plate 305b.

The microwaves propagating in the coaxial waveguide 310 propagate in the dielectric plate 305b and propagates to the dielectric window 307 from the plurality of slot holes of the slot plate 305c. The microwaves propagating in the dielectric window 307 are radiated into the processing space S from the bottom surface of the dielectric window 307.

A gas pipe 311 is provided inside the inner conductor 310b of the coaxial waveguide 310. A through-hole 305d through which the gas pipe 311 can pass is formed in the central portion of the slot plate 305c. The gas pipe 311 extends through the inside of the inner conductor 310b, and is connected to a gas supply part 312.

The gas supply part 312 supplies a processing gas for processing the substrate W to the gas pipe 311. The gas supply part 312 includes a gas source 312a, a valve 312b, and a flow rate controller 312c. The gas source 312a is a source of the processing gas. The valve 312b controls the supply and cutoff of the processing gas from the gas source 312a. The flow rate controller 312c is, for example, a mass flow controller or the like, and controls a flow rate of the processing gas supplied from the gas source 312a.

The gas source 312a is a source of a processing gas for forming a sealing film. The processing gas includes a nitrogen-containing gas, a silicon-containing gas, and a noble gas. In the present embodiment, the nitrogen-containing gas is, for example, a NH₃ gas or a N₂ gas. The silicon-containing gas is, for example, a SiH₄ gas, and the noble gas is, for example, a He gas or an Ar gas. Although not illustrated, the gas supply part 312 supplies a cleaning gas into the processing space S via the gas pipe 311. As the cleaning gas, for example, a NF₃ gas, a H₃ gas, an O₂ gas or the like is used. When the cleaning gas supplied into the processing space S is formed into plasma by microwaves, reaction byproducts adhering to the inside of the processing container 301 or the like are removed by radicals or the like contained in the plasma.

An injector 313 is provided inside the dielectric window 307. The injector 313 injects the processing gas supplied through the gas pipe 311 into the processing space S through a through-hole 307h formed in the dielectric window 307. The processing gas injected into the processing space S is excited by the microwaves radiated into the processing space S through the dielectric window 307. As a result, the processing gas is plasmarized inside the processing space S, and a sealing film is laminated on the substrate W by ions, radicals and the like contained in the plasma. In the present embodiment, the sealing film is, for example, a silicon nitride film.

### [Annealing Apparatus 400]

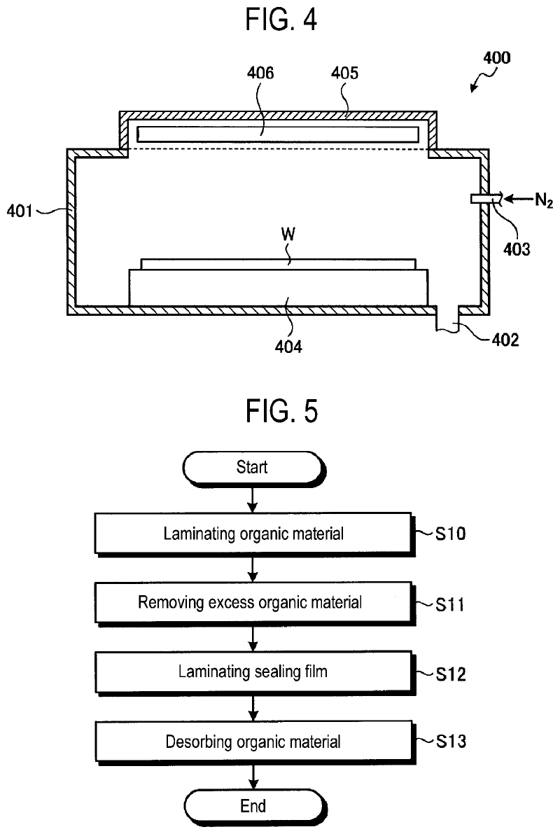

FIG. 4 is a schematic cross-sectional view illustrating an example of the annealing apparatus 400 according to an embodiment of the present disclosure. The annealing apparatus includes a container 401 and an exhaust pipe 402. An inert gas is supplied into the container 401 through a supply pipe 403. In the present embodiment, the inert gas is, for example, a N₂ gas. The gas inside the container 401 is exhausted from the exhaust pipe 402. In the present embodiment, the inside of the container 401 has a normal pressure atmosphere. In some embodiments, the inside of the container 401 may have a vacuum atmosphere.

A stage 404 is provided inside the container 401 so as to place the substrate W thereon. A lamp house 405 is provided at a position facing the surface of the stage 404 on which the substrate W is placed. An infrared lamp 406 is disposed inside the lamp house 405.

The inert gas is supplied into the container 401 in the state in which the substrate W is placed on the stage 404. Then, the substrate W is heated by turning on the infrared lamp 406. When the temperature of the organic material laminated in the recess of the substrate W reaches a predetermined temperature, the organic material is thermally-decomposed into two types of raw material monomers. In the present embodiment, since the organic material is polyurea, when the substrate W is heated to 300 degrees C. or higher, for example, 500 degrees C., the organic material is depolymerized into isocyanate and amine, which are raw material monomers. Then, the isocyanate and amine generated by the depolymerization pass through the sealing film laminated on the organic material, whereby the organic material in the recess of the substrate W is desorbed. As a result, an air gap is formed between the recess in the substrate W and the sealing film.

### [Method of Forming Air Gap]

FIG. 5 is a flowchart illustrating an example of a semiconductor device manufacturing method. First, when the substrate W having a recess formed therein is loaded into the laminating apparatus 200, the process illustrated in FIG. 5 begins.

First, a thermally-decomposable organic material is laminated on the substrate W using the laminating apparatus 200 (S10). Step S10 is an example of a first laminating step. As a result, as illustrated, for example, in FIG. 6, an organic material 51 is laminated in the recess 50 of the substrate W. Then, the substrate W is unloaded from the laminating apparatus 200 by the transfer mechanism 106, and is loaded into the annealing apparatus 400.

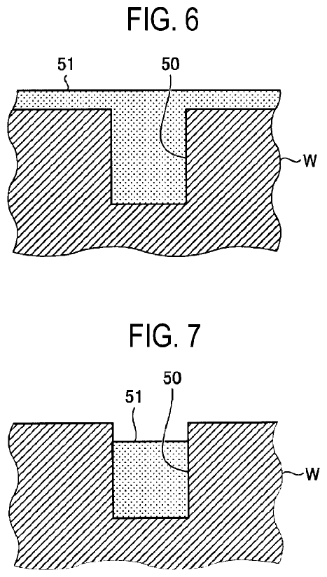

Subsequently, the substrate W is heated by the annealing apparatus 400 so that the excess organic material laminated on the substrate W is removed (S11). In step S11, the substrate W is heated by the annealing apparatus 400 to a temperature, for example, from 200 degrees C. to 300 degrees C. As a result, as illustrated, for example, in FIG. 7, the organic material 51 laminated on the top surface of the substrate W is desorbed by thermal decomposition, and the organic material 51 remains in the recess 50. Then, the substrate W is unloaded from the annealing apparatus 400 by the transfer mechanism 106, and is loaded into the plasma processing apparatus 300.

Subsequently, a sealing film is laminated on the substrate W by the plasma processing apparatus 300 (S12). Step S12 is an example of a second laminating step. Main film-forming conditions for the sealing film in step S12 are, for example, as follows.

Temperature of substrate W: 150 degrees C.

Processing gas: NH₃=10 sccm, SiH₄=10 sccm, and He=300 sccm

Internal pressure of processing container 301: 20 Pa

Microwave power: 500 W

The temperature of the substrate W may be in a range of, for example, 100 degrees C. to 200 degrees C. The flow rates of the NH₃ gas and the SiH₄ gas may be in a range of, for example, 5 sccm to 20 sccm. The flow rate of the He gas may be in a range of, for example, 100 sccm to 500 sccm. The internal pressure of the processing container 301 may be in a range of, for example, 10 Pa to 100 Pa. In addition, the microwave power may be in a range of, for example, 100 W to 1,000 W.

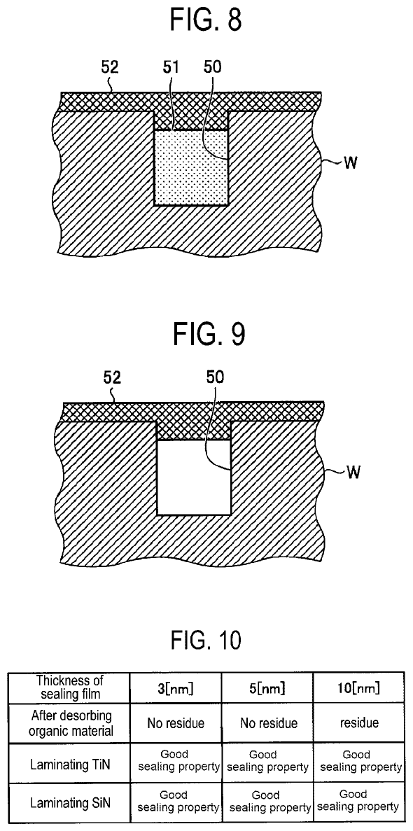

As a result, as illustrated, for example, in FIG. 8, a sealing film 52 is laminated on the organic material 51 in the recess 50 of the substrate W. Then, the substrate W is unloaded from the plasma processing apparatus 300 by the transfer mechanism 106, and is loaded into the annealing apparatus 400 again.

Subsequently, the substrate W is heated by the annealing apparatus 400 so that the organic material 51 in the recess 50 is desorbed (S13). Step S13 is an example of a desorption step. In step S13, the substrate W is heated to, for example, 400 degrees C. or higher by the annealing apparatus 400. As a result, the organic material 51 between the sealing film 52 and the recess 50 is desorbed through the sealing film 52 so that, for example, as illustrated in FIG. 9, an air gap having a shape corresponding to the shape of the organic material 51 is formed between the sealing film 52 and the recess 50. Then, the process illustrated in this flowchart ends.

### [Test Results]

When the film density of the sealing film 52 is too high, the thermally-decomposed organic material 51 cannot pass through the sealing film 52, and may remain as a residue in the recess 50 of the substrate W. Thus, it becomes difficult to form an air gap having a desired shape between the recess 50 and the sealing film 52. In addition, when the film density of the sealing film 52 is too low, the thermally-decomposed organic material 51 is desorbed through the sealing film 52. However, when another film is laminated on the sealing film 52 in a subsequent step, the another film may be laminated in the recess 50 through the sealing film 52. Even in this case, it becomes difficult to form an air gap having a desired shape between the recess 50 and the sealing film 52.

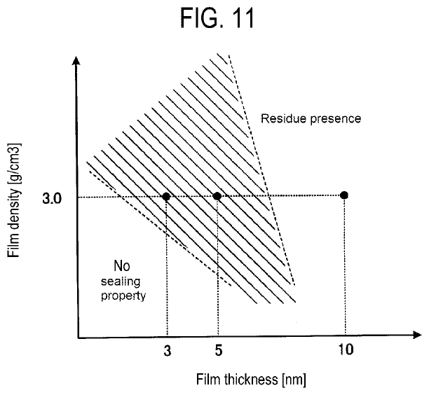

Accordingly, a test was performed to examine the presence or absence of the residue and the sealing property using the sealing film 52 laminated according to the present embodiment. FIG. 10 is a view showing an example of the test results. In the test of FIG. 10, the sealing property of the sealing film 52 on which TiN and SiN are laminated was examined. As a result of measuring the film density of the sealing film 52 laminated according to the present embodiment, the film density was 3.0 g/cm³.

For example, as shown in FIG. 10, when the thickness of the sealing film 52 was in the range of 3 nm to 5 nm, no residue was observed in the recess 50. That is, when the thickness of the sealing film 52 was in the range of 3 nm to 5 nm, it was possible to sufficiently desorb the organic material in the recess 50 through the sealing film 52.

For example, as shown in FIG. 10, when the thickness of the sealing film 52 was in the range of 3 nm to 10 nm, even when TiN or SiN was laminated on the sealing film 52, no lamination of TiN or SiN was observed in the recess 50. That is, when the thickness of the sealing film 52 was in the range of 3 nm to 10 nm, the sealing film 52 has a good sealing property.

In addition, TiN was laminated on the sealing film 52 through, for example, thermal atomic layer deposition (ALD) under, for example, the following conditions.

Temperature of substrate W: 400 degrees C.

Precursor gas: TiCl₄

Reaction gas: NH₃

Pressure: 10 Pa

In addition, SiN was laminated on the sealing film 52 through, for example, thermal atomic layer deposition (ALD) under, for example, the following conditions.

Temperature of substrate W: 600 degrees C.

Precursor gas: dichlorosilane (DCS)

Reaction gas: NH₃

Pressure: 10 Pa

With reference to the test results of FIG. 10, in a shaded region shown, for example, in FIG. 11, it is considered that it is possible to laminate the sealing film 52 having no residue and having a good sealing property. Since the film density of the sealing film 52 in the present embodiment is 3.0 g/cm³, the film thickness of the sealing film 52 is preferably in the range of 3 nm to 5 nm from the viewpoint of having no residue and a good sealing property. The film density of the sealing film 52 in the present embodiment is 3.0 g/cm³, but when the sealing film 52 has a film density of the range of 2.3 g/cm³ to 3.3 g/cm³, it is possible for the sealing film 52 to have no residue and to have a good sealing property.

The embodiments have been described above. As described above, the semiconductor device manufacturing method according to the present embodiment may include the first laminating step, the second laminating step, and the desorbing step. In the first laminating step, the thermally-decomposable organic material 51 is laminated on the substrate W having the recess 50 formed therein. In the second laminating step, the sealing film 52 made of a silicon nitride film is laminated on the organic material 51. In the desorbing step, the substrate W is heated to a predetermined temperature to thermally decompose the organic material 51 and to desorb the organic material 51 under the sealing film 52 through the sealing film 52, thus forming an air gap between the sealing film 52 and the recess 50. In the second laminating step, the sealing film 52 is laminated using microwave plasma in the state in which the temperature of the substrate W is maintained at 200 degrees C. or lower. As a result, it is possible to form an air gap having a desired shape.

In the above-described embodiment, the sealing film 52 is laminated on the organic material 51 at a thickness ranging from 3 nm to 5 nm. This makes it possible to form an air gap having a desired shape.

In the above-described embodiment, the organic material 51 is a polymer having a urea bond generated by polymerization of multiple types of monomers. This makes it possible to form an air gap having little residue.

In addition, the manufacturing system 10 according to the embodiments described above includes the laminating apparatus 200, the plasma processing apparatus 300, and the annealing apparatuses 400. The laminating apparatus 200 laminates the thermally-decomposable organic material 51 on the substrate W having the recess 50 formed therein. The plasma processing apparatus 300 uses plasma to laminate the sealing film 52 made of a silicon nitride film on the substrate W on which the organic material 51 has been laminated. The annealing apparatus 400 heats the substrate W on which the organic material 51 has been laminated to a predetermined temperature to thermally decompose the organic material 51, and to desorb the organic material 51 under the sealing film 52 through the sealing film 52, thus forming an air gap between the sealing film 52 and the recess 50. The plasma processing apparatus 300 includes the processing container 301, the stage 302, the heater 302d, and the microwave output device 304. The stage 302 is provided inside the processing container 301, and the substrate W is placed on the stage 302. The heater 302d controls the temperature of the substrate W placed on the stage 302 to 200 degrees C. or lower. The microwave output device 304 supplies microwaves into the processing container 301 so as to plasmarize the gas supplied into the processing container 301. By the plasma, the sealing film 52 is formed on the substrate W on which the organic material 51 has been laminated. This makes it possible to form an air gap having a desired shape.

### [Others]

The technology disclosed herein is not limited to the embodiments described above, and various modifications are possible within the scope of the gist of the present disclosure.

For example, in the embodiments described above, the polymer having a urea bond is used as an example of the polymer constituting the organic material 51. However, a polymer having a bond other than the urea bond may be used as the polymer constituting the organic material 51. The polymer having a bond other than the urea bond may be, for example, polyurethane having a urethane bond, or the like. The polyurethane may be synthesized, for example, by copolymerizing a monomer having an alcohol group and a monomer having an isocyanate group. In addition, the polyurethane may be heated at a predetermined temperature to be depolymerized into a monomer having an alcohol group and a monomer having an isocyanate group.

In addition, the manufacturing system 10 according to the embodiments described above includes the laminating apparatus 200, the plasma processing apparatus 300, and the plurality of annealing apparatuses 400, but the disclosed technology is not limited thereto. For example, the manufacturing system 10 includes a plasma processing apparatus that performs a process with capacitively-coupled plasma (CCP) generated using parallel plates, in place of any one of two annealing apparatuses 400. In this case, the substrate W on which the organic material 51 has been laminated in the recess 50 in step S10 is unloaded from the laminating apparatus 200 by the transfer mechanism 106, and is loaded into the plasma processing apparatus using capacitively-coupled plasma. Then, by plasma of the processing gas generated by the plasma processing apparatus, an excess organic material laminated on the substrate W is removed. As the processing gas at this time, a H₂ gas or an O₂ gas may be used.

According to various aspects and embodiments of the present disclosure, it is possible to form an air gap having a desired shape.

It should be noted that the embodiments disclosed herein are exemplary in all respects and are not restrictive. Indeed, the above-described embodiments may be implemented in various aspects. Further, the above-described embodiments may be omitted, replaced or modified in various forms without departing from the scope and spirit of the appended claims.

What is claimed is:

1. A semiconductor device manufacturing method, comprising:
laminating a thermally-decomposable organic material on a substrate having a recess formed therein;
laminating a silicon nitride film on the organic material; and
heating the substrate to a predetermined temperature so as to thermally decompose the organic material, and to desorb the organic material under the silicon nitride film through the silicon nitride film so as to form an air gap between the silicon nitride film and the recess,
wherein in laminating the silicon nitride film, the silicon nitride film is laminated on the organic material with microwave plasma in a state in which a temperature of the substrate is maintained at 200 degrees C. or lower.

2. The semiconductor device manufacturing method of claim 1, wherein the silicon nitride film is laminated on the organic material at a thickness ranging from 3 nm to 5 nm.

3. The semiconductor device manufacturing method of claim 2, wherein the organic material is a polymer having a urea bond generated by polymerization of multiple types of monomers.

4. The semiconductor device manufacturing method of claim 1, wherein the organic material is a polymer having a urea bond generated by polymerization of multiple types of monomers.

5. A semiconductor device manufacturing system, comprising:
a laminating apparatus configured to laminate a thermally-decomposable organic material on a substrate having a recess formed therein;
a plasma processing apparatus configured to laminate a silicon nitride film on the substrate, on which the organic material has been laminated, using plasma; and
an annealing apparatus configured to heat the substrate, on which the silicon nitride film has been laminated, to a predetermined temperature so as to thermally decompose the organic material, and to desorb the organic material under the silicon nitride film through the silicon nitride film so as to form an air gap between the silicon nitride film and the recess,
wherein the plasma processing apparatus includes:
a processing container;
a stage provided inside the processing container and configured to place the substrate thereon;
a temperature controller configured to control a temperature of the substrate placed on the stage to 200 degrees C. or lower; and
a plasma processing part configured to supply microwaves into the processing container to form a gas supplied into the processing container into plasma and to laminate, by the plasma, a silicon nitride film on the substrate on which the organic material has been laminated.
